(19) United States
(12) Patent Application Publication
(10) Pub. No.: US 2003/0155842 A1
(43) Pub. Date: Aug. 21, 2003

(54) Piezo actuator

(76) Inventor: Maximilian Hans Hobelsberger, Wuerenlingen (CH)

Correspondence Address: Maximilian H. Hobelsberger, Dorfstr. 16, Wuerenlingen, 5303, CH

(21) Appl. No.: 10/364,975

(22) Filed: Feb. 13, 2003

Related U.S. Application Data
(60) Provisional application No. 60/357,685, filed on Feb. 19, 2002.

(51) Int. Cl. H01L 41/08

(52) U.S. Cl. 310/331

(57) ABSTRACT

The actuator consists typically of two thin strips of material. One strip is made of e.g. steel. One surface of this strip is structured with tooth-like projections. To the tips of these teeth a second strip is attached. The second strip consists of e.g. piezoelectric material and is equipped with electrodes. Upon application of voltage the second strip changes its length and bends via the attached teeth the whole structure. The teeth-like structures provide stronger bending torque. The structure can also be used as a micromachined motor.

### REFERENCES TO RELATED APPLICATIONS

Reference is made to the correspondung provisional application No. 60/357,685 to claim priority under 35 USC 119(e).

### BACKGROUND OF THE INVENTION

1. Field of the Invention

This invention relates to electromechanical transducers which transform electrical energy into mechanical energy. More particularly, the invention relates to a piezo transducer or other transducers which use materials which shrink or expand upon application of electrical or magnetic fields or influence of temperature changes.

2. Prior Art

Piezo transducers are well known and much used for applications where small and precise mechanical displacements are needed. These displacements are in the range of some 10 um. Piezo materials (or also magnetostrictive materials) contract or expand when electrical (or magnetic) fields are applied to the materials. These expansions are quite small but sufficient for many applications. A strip of PVDF—foil (20 um thick) for example of 3 cm length will change its length by 15 um upon application of 200 V between back and front surface.

Other applications include electroacoustic transducers, i.e. loudspeakers for high frequency tones.

However other applications would require larger rates of displacement.

One basic mechanism used for actuators is mechanical bending. For this two strips of material are glued together at their surfaces. If one strip expands relatively to the other strip the whole element will be bent. A good example is the bimetal strip which bends due to the different rates of thermal expansion of the two metals used.

In the literature a basic bending element of this kind is shown in “AMP—manual for PVDF piezo-foil”.

### SUMMARY OF THE INVENTION

It is an object of this invention to provide an improved version of a bending actuator which consists of two or more strips of material attached to each other.

A closer look at the basic bending strip, called some times the “bimorph”, reveals, that just glueing or putting together both strips of materials will produce poor results. This is because the expansion strain of one strip will not completely be transformed into a bending torque exercised upon the other strip, but will try to expand also the other strip. Due to the high forces which are needed for compression or expansion of the solid materials used only a small expansion or contraction or bending will result.

The piezo-actuator or bimorph according to the invention avoids these problems and achieves relatively large bending displacements at low voltages or low field strengths.

One important use of this actuator is in acoustical systems. An other application is as motor or moving element.

The basic device comprises two members, i.e. strips of material. The first strip consists of e.g. metal, i.e. steel or gold, or of other high strength/tensility material (thin sheets of glass, silicon). This strip is flexible, i.e. easily bendable, but not expandable or compressible. One surface of the strip is micro-structured, i.e. equipped with a multitude of teeth seperated by grooves or slits.

The second strip consists of piezoactive (e.g. PVDF or PZT or other) or magnetostrictive material and is glued or otherwise attached to the tips of the teeth or tooth-shaped projections of the first strip. This piezo-strip is also flexible, and it is equipped with electrical conducting electrodes on both surfaces. Upon application of voltage the piezo-strip contracts or expands. This contraction or expansion is transformed by the attached teeth into a bending torque exercised on the first strip which is bent by this force. This is the basic mechanism: The expansion or contraction of the piezo-strip or active member is converted by the teeth into a torsional torque which acts upon the first strip and bends it. So the whole structure is bent as result.

For a fuller understanding of the nature of the invention, reference should be made to the following detailed description of the preferred embodiments of the invention, considered together with the accompanying drawings.

### BRIEF DESCRIPTION OF THE DRAWINGS

FIG. 1 is a cut view and normal view of the basic bending element.

FIGS. 2a, 2b show the principle of operation.

FIGS. 3a, 3b, 3c, 3d show a preferred shapes of teeth.

FIG. 4 shows an element with embedded active material.

FIG. 5 shows an actuator with improved strength.

FIGS. 6, 7 and 8 depict a micro-motor.

FIGS. 9, 10, 11, 12 show high displacement sensors.

FIG. 13 shows a compound actuator.

### DESCRIPTION OF THE PREFERRED EMBODIMENTS

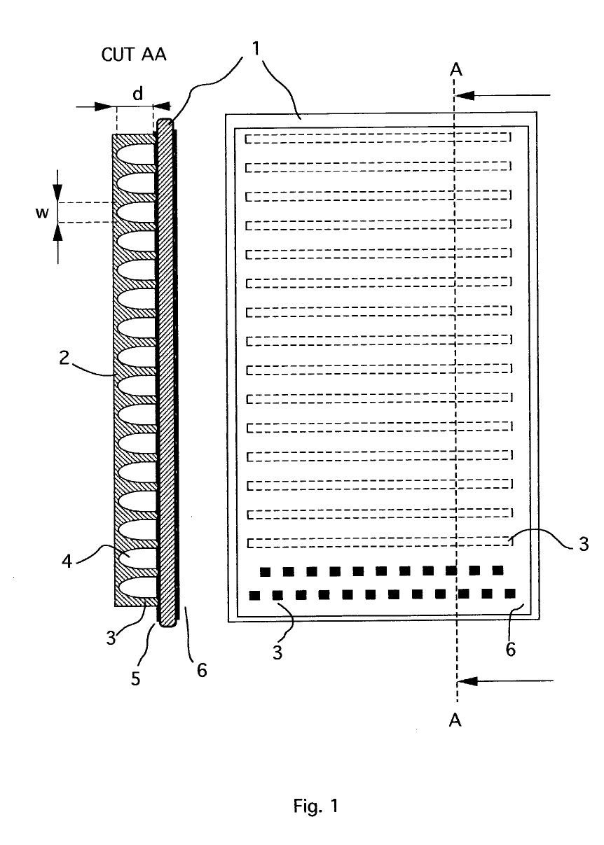

The following is a description of a first, preferred embodiment of the invention and refers to FIG. 1.

The basic device consists of two strips or members of material. Two surfaces of the strips are mechanically attached to each other by glueing, soddering etc.

The first strip, 1, called also the active strip or member, consists of e.g. piezoelectric material which changes its length upon application of an electrical field. For generation of this electrical field conducting electrodes, 5, 6 are applied to the surface of strip 1.

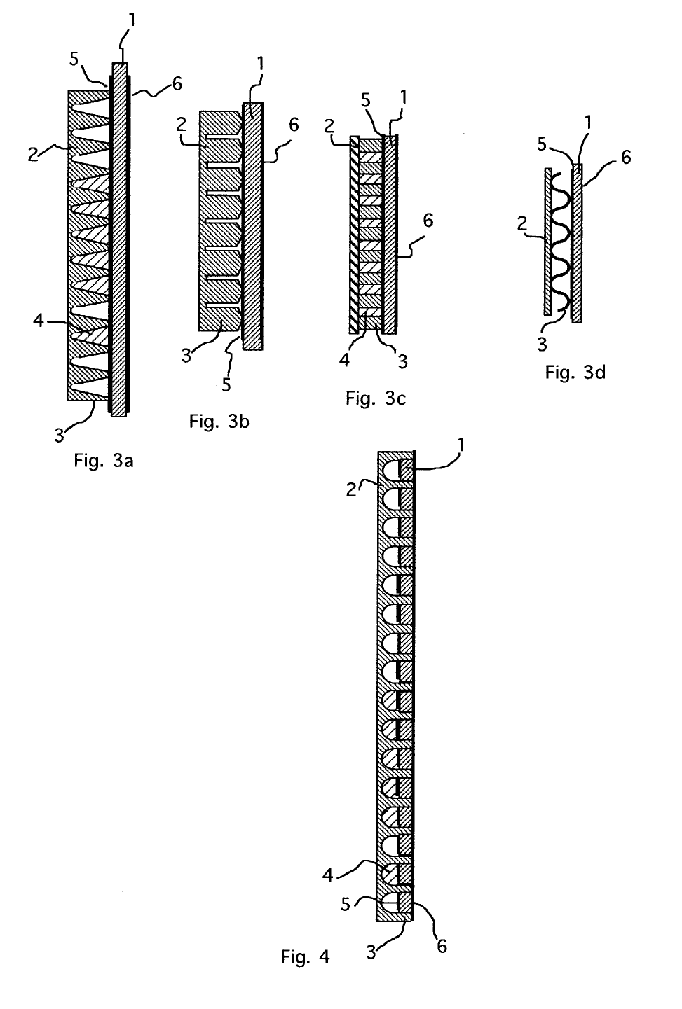

The second strip or member, 2, also called the base strip, consists preferably of material which has a high modulus of elasticity but which is not brittle, e.g. high quality steel. It should be flexible in thin layers, but not easily expandable or compressible. One surface of this second strip is equipped with teeth or tooth-shaped projections 3. These teeth have a length of d and they are spaced apart by w. The teeth 3 are separated by grooves or slots 4 which are filled with air or gas or a material which is easily to compress or stretch. The shape of the teeth or projections can be cellular (lower part of FIG. 1), in stripes (upper part of FIG. 1), or separated by trenches or slits etc. The dimensions of teeth and grooves are chosen such that the teeth are preferably less bendable than the remaining parts of the strip at the bottom of the grooves 4. In addition it can be seen that in FIGS. 1, 3a, 3b that the teeth are firmly connected to the base strip 2 by a broad base so that torsional torque will be stransfered from the teeth to the base strip and bend the base strip. The tips of the teeth are connected to the active strip only at narrow strips- or points. This is to not hinder the expansion/contraction of the active strip. In FIG. 1 the groove has a curved bottom which leaves only a thin, narrow layer of material at the deepest point of the groove which in fact acts more like a hinge for the adjacent teeth. Typical dimensions would be d=20 um, w=20 um, the remaining thickness of the strip at the bottom of the grooves would be e.g. 2 um. In FIG. 3a the teeth have triangular shape, in FIG. 3b they are rectangular. It should be noted that the teeth are attached to the active strip 1 only at their narrow tips so that the active (piezo) material can freely expand or contract. The active strip 1 consists of piezoelectric materials like PVDF or PZT or piezofibers or the like. Electrodes 5 and 6 are applied to the two surfaces of the active strip. The electrodes should be easily stretchable, i.e. materials like silver-ink should be used. If voltage is applied between the two electrodes the active strip contracts or expands depending on the polarity of the voltage. However it will change its length just by a small percentage of the length. In the example above the PVDF film would change by 15 um on a total length of 3 cm, that is 0.05%. However due to the microstructure of the base-strip with the teeth and the small dimensions a large overall bending will occur. Each rectangular cell which consists of two adjacent teeth as the two sides and the top and bottom strip parts will contribute a change of angle of approximately

(0.05*20/100)/20=0.0005 rad ==0.029 degrees

The strip of 3 cm length consists of 1500 cells which gives an overall angle of 43 degrees. A microstructure with 10 um-cells would give 86 degrees. So the huge amount of cells gives a considerable angle of bending. The actual amount of bending can be chosen by the dimensions of basic cells, i.e. length of teeth and width of cell.

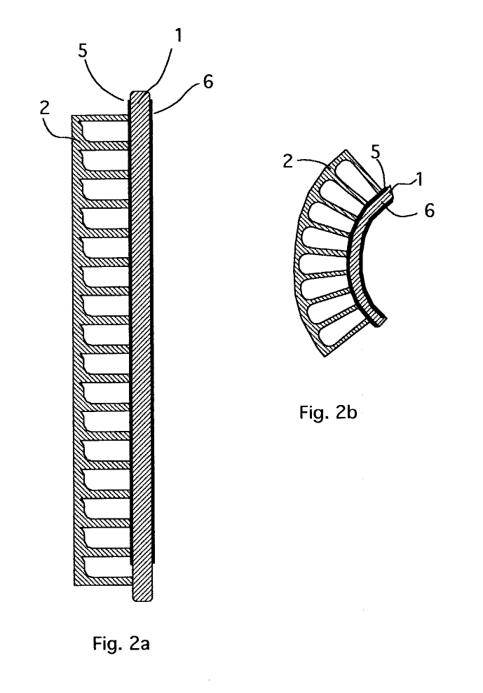

An important effect is that the teeth transform the change of length into a bending, i.e. torsional torque acting upon the base-strip 2. Without teeth a considerable part of the force created by the electric field on the piezo material would be a strain force, not a torque. By using teeth a considerable part of the overall force is transformed into a bending force, i.e. into torque which bends the whole element. This mechanism of bending is shown in FIG. 2a, FIG. 2b.

It should be noted that the active strip 1 can be made of any material which changes length upon application of external influences. It could be magnetostrictive material which reacts to magnetic fields, or it could be just a strip of conducting material which changes length when it is heated by electrical current or by direct contact with a warmer medium.

FIG. 3a shows an element with triangular teeth on the base-strip, FIG. 3b shows an element with more rectangular teeth. These shapes are used to prevent too much bending of the teeth. In FIG. 3c an intermediate sheet of structured material is glued or attached in between the active strip 1 and the base strip 2. This intermediate sheet of material consists again of strong, mechanically firm teeth 3 and soft material 4 between the teeth. In FIG. 3d the intermediate sheet is pressed and formed into a curved/rippled shape or profile. These curves or waves of material act as teeth 3.

FIG. 4 shows an element with the active (piezo) material attached between the teeth. This can help to prevent cracking of brittle piezo materials.

An appropriate method of producing these trips is to imprint the grooves or slits beteen the tooth-shaped projections by rolling with a reliefed roller or wheel of sufficient width over the surface of the base-strip material 2 and pressing grooves into the material. These grooves can then be filled with flexible material or just left open to the air or gas. Afterwards the sheet of piezo-material (equipped with electrodes) is applied and connected to the teeth by glueing or soddering. Or the active material is sputtered onto the surface (after filling the grooves with flexible material) and then equipped with electrodes.

It is also possible to grow these structures by e.g. chemical vapor deposition on some base substrates (e.g. silicon) and produce the structures by the methods called micromachining, e.g. etching of grooves and depositing further layers of material etc.

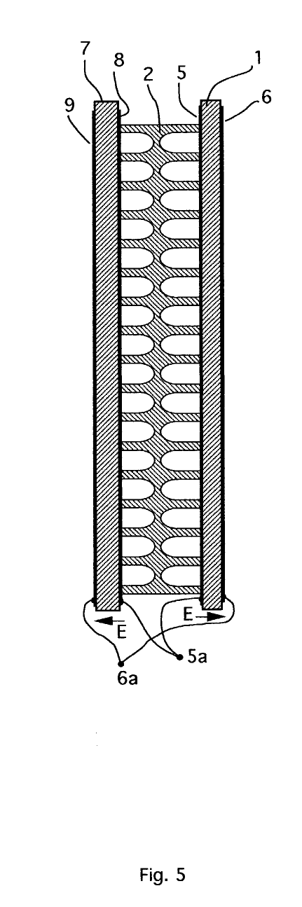

FIG. 5 shows an other preferred embodiment which produces twice the bending force. It consists of a sheet or base-strip of base-material 2 which is equipped on both surfaces with teeth. On both surfaces, at the tips of the teeth, strips of active material 1, 7 are attached. Again these two active strips are equipped with conducting electrodes 8 and 9, and 5, 6. By applying voltages of opposite polarity to the electrodes one active strip is expanding when the other active strip is contracting. The electrical connections are shown in FIG. 5. The whole element gains on bending torque and on mechanical stability.

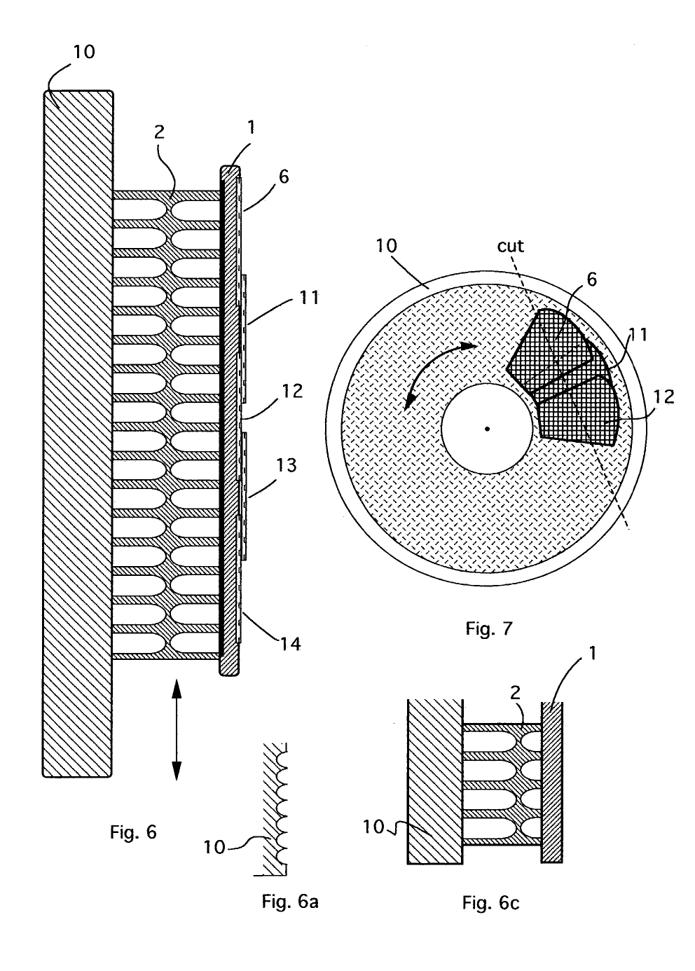

FIGS. 6 and 7 show a motor based on this technology. Again a base-strip with teeth on both surfaces is used. However only one surface is equipped with the active material 1 which moves the teeth. When an electrical voltage is applied between the electrode 5 and the electrodes 6, 11, 12, 13, 14 the teeth are moved. The electrodes are arranged in different, partly overlaying patterns and segments such that a moving wave-effect of the teeth can be created if individual voltages with different phase-shifts are applied to the individual electrode segments (e.g. three-phase-motor principle/well known moving field principle created by multi-phase systems with multiple, phaseshifted sinusoidal voltages applied to multiple locally space-shifted electrodes). This e.g. circular (circular in relation to a imaginary point of reference on the base-strip) movement of the teeth causes a relative motion of the base-strip 2 in relation to the base-plate 10. It should be noted that also a motor with piezomaterial on both teeth-surfaces of base-strip 2 in analogy to the element of FIG. 5 may be used if the piezomaterial is sufficiently wear-resistant. However, teeth are advantageous if the surface of the baseplate is also structured to provide more grip for the teeth. FIG. 6a shows a structured surface of baseplate 10. FIG. 6c depicts a base-strip 2 with teeth of different lengths at both surfaces. This can be useful to adjust to different torque or speed requirements.

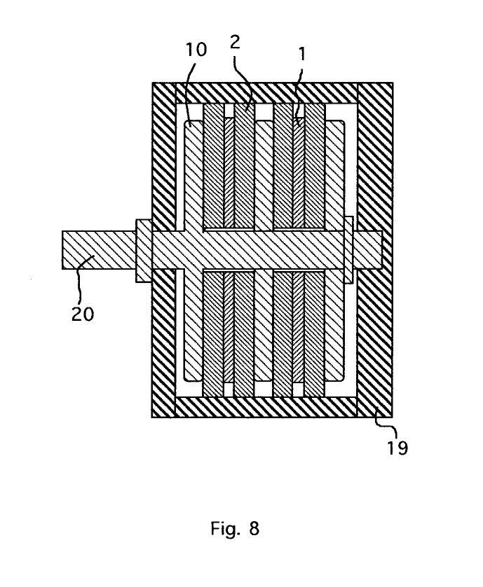

FIG. 8 shows a cut-view of a motor consisting of a stack of elements of FIG. 6. Three baseplate-disks 10 are driven by four disks of base-strip 2 which are equipped with teeth. Between each pair of base-strips 2 the active strips 1 are arranged. The base-strip disks 2 are circumferentially connected to the housing 19. The three disks 10 of base-plate are connected to the rotor shaft 20. It should be understood that a huge number of disks could be stacked to increase torque.

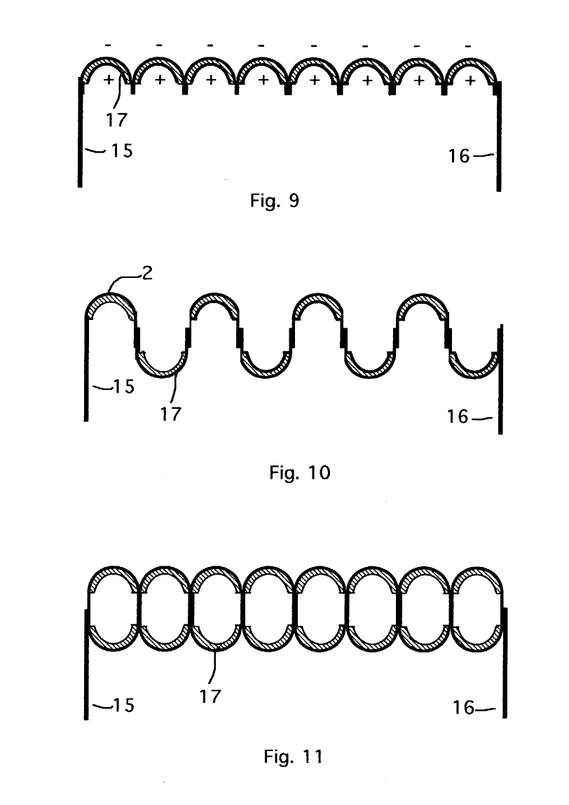

FIG. 9 depicts a cut-view of a bending element which consists of several basic, arched bending segments 17 which are mechanically connected to each other at their ends. These basic segments are bending elements according to FIGS. 1-5 or similar. By arranging a whole chain of elements greater rates of deflection are possible at the same voltage then with only one basic element. 15, 16 show handles which are moved by the elements. By the “+” and “−” signs it is shown that electrical fields with the same direction are applied to the elements to increase the deflection. FIGS. 10, 11 show cut-views of similar devices which consist of several basic bending elements.

It should be noted that the bending elements of FIGS. 9-11 could also be made of only one or more basic elements which are bent at production into several arches and which are equipped with appropriate electrodes. The elements of FIGS. 10, 11 can preferably be used for translational displacement, i.e. linear movement.

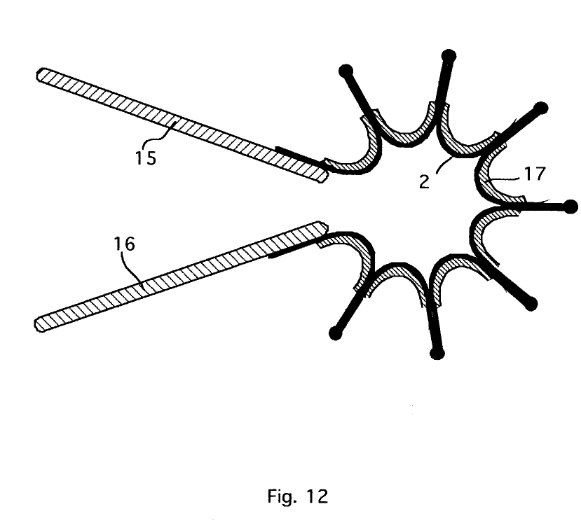

FIG. 12 shows a cut-view of an element similar to the element of FIG. 9. The individual base-elements 17 are arranged in a star-shape such that the handles 15, 16 are close together.

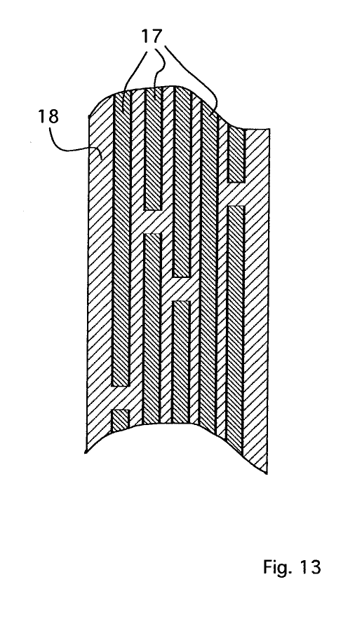

FIG. 13 shows a cut-view of a bending element which is a compound of several base elements according to FIGS. 1-5. The individual bending elements or sheets are mebedded into flexible material like rubber or plastic. They can glide or be displaced in local relation to each other due to the material which is spread between them. By stacking several layers of active bending elements it is possible to increase the bending force.

To summerize, the new mechanical actuator comprises

at least two members (e.g. strips or sheets of material) which are mechanically connected (there is a mechanical link between the parts or members) to each other by a multitude of tooth-shaped projections (e.g. teeth or ridges seperated by trenches or grooves),

wherein said projections (the teeth) are in substantially firm mechanical connection (e.g. glued or soddered to, or the teeth are part of the member) with at least one of said members such that torsional torque exercised on said projections will be transferred to said member (the teeth do not easily bend) to which said projections are firmly connected so that said torque is also exercised on said member (and bends it) to which said projections is firmly connected,

wherein at least one of said members alters its dimensions (changes length or width or both) when being affected by external influences (electrical field, magnetical field, heat etc.) such that the distance between adjacent projections connected to said member is altered (i.e. the tips of the teeth move closer or farther apart),

whereby said alteration in distance between projections causes bending torque being exercised on said projections and said members connected to the projections (and the torque bends the element).

A more specific actuator comprises two members,

wherein the first member consists of substantially strong and flexible material (e.g. steel or glass fiber),

wherein one surface of said first member is processed such that a multitude of projections (teeth) projects from said surface,

wherein a second member is mechanically connected (glued, soddered, welded etc.) to the tips (i.e. the end region) of said projections,

and wherein said second member consists of material (e.g. piezo-material, ferroelectric material, magnetostrictive material) which substantially changes its dimensions (shrinks or expands) when being subjected to external influences and therefore changes the distances between adjacent tips of said projections.

In the actuator above the first member (which is equipped with teeth) may consist of metal (e.g. steel).

The second member consists of piezo-active material (e.g. PVDF, PZT or other piezoelectric or feroelectric material) which is equipped with electrodes for application of voltage between the electrodes (and generation of an electrical field which affects the piezo-material).

The second member may also consist of electrically conducting material (gold, copper etc.),

wherein said second member is caused to change its temperature by electrical current applied to it (via connectors or leads to a power source),

and whereby the changes in dimensions (i.e. distance between tips of teeth) caused by the changes in temperature bend the actuator.

A further improvement for certain applications concerns an actuator which comprises three members,

wherein the middle member consists of substantially strong and flexible material (e.g. steel),

wherein two adjacent surfaces of said middle member (the two surfaces of the middle strip) are processed such that a multitude of projections (teeth or ridges) projects from said surfaces,

wherein a second member is mechanically connected to the tips (the end regions) of said projections at one of said surfaces of said middle member,

wherein a third member is mechanically connected to the tips of said projections at the other one of said surfaces of said middle member, (so on both sides of the middle strip active strips are attached)

and wherein said second and third members consist of material which substantially changes its dimensions when being subjected to external influences and therefore changes the distances between adjacent tips of said projections connected to said second and third members. Of course the external influences (e.g. electrical field) must be applied in opposite directions, orientations or strengths to these active strips (second and third member) so that when one member expands the other member contracts which causes the element to bend.

Again the middle member may consist of metal, and the second and third members may consist of piezo-active material which is equipped with electrodes.

This is now an actuator which can move along a surface or which can be used as motor. Its second member (e.g. the surface on which it moves) is mechanically disconnected from said tips of said projections adjacent to its surface,

and wherein said third member is equipped with a multitude of electrodes (which may be overlapping or interleaved) which allow a structured movement (e.g. kind of moving wave) of said tips of said projections relative to said second member (the individual tips could move along a circle-trajectory in relation to a hypothetical plane which moves in parallel with the active member/strip/plane),

whereby by appropriate steering (e.g. a multitude of phaseshifted voltages) of said structured movement an overall movement of said second member in relation to the other members is achieved.

The length of the projections or teeth may differ on different surfaces, i.e. at one surface they may be longer than at the other surface of the middle member. This is to allow adjustment of speed and torque.

For more power the actuator/motor may comprise a multitude of (disk-shaped) actuators as described above, which are centrally aligned along a central shaft, and a housing,

wherein said second members are mechanically connected to said shaft and said middle and third members are disconnected from the shaft (the shaft goes through holes in the disks/members) but connected to a surrounding housing, such that by appriopriate excitation of said electrodes a turning movement of the shaft in relation to the housing is achieved.

An other actuator may comprise a multitude of (active) sub-segments, which are pre-bent (so the sub-segment is already bent without activation) and arranged in a chain such that a small bending of said sub-segments results in a substantially larger overall displacement of the ends of said chain in relation to each other. This is useful if a large linear displacement shoul be achieved.

A special version of the above actuator consists of a double row of said sub-segments, wherein the sub-segments of one row are interconnected at their ends with the sub-segments of the other row. This is shown in FIG. 11. The actuator will produce mainly linear displacement.

Another version which may be appropriate has the sub-segments arranged in the shape of a star (FIG. 12).

Many individual actuators may also be embedded into a sheet (or matrix) of substantially flexible material (e.g. rubber). This allows to increase the bending force (FIG. 13). The influences (e.g. electrical voltage) may be applied to all in parallel, or also individually with different strengths to cause non-uniform displacements.

While the present invention has been described in connection with particular embodiments thereof, it will be understood by those skilled in the art that many changes and modifications may be made without departing from the true spirit and scope of the present invention. Different types of active strips may be used, and several kinds of different shapes of projections or bending element or element assembly. Therefore, it is intended by the appended claims to cover all such changes and modifications which come within the true spirit and scope of this invention.

What is claimed is:

1. Mechanical actuator, comprising
at least two members which are mechanically connected to each other by a multitude of tooth-shaped projections,
wherein said projections are in substantially firm mechanical connection with at least one of said members such that a torsional torque exercised on said projections will be transferred to said member to which said projections is firmly connected so that said torque is also exercised on said member to which said projections is firmly connected,
wherein at least one of said members alters its dimensions when being affected by external influences such that the distance between adjacent projections connected to said member is altered,
whereby said alteration in distance between projections causes bending torque being exercised on said projections and said members connected to the projections.

2. Actuator according to claim 1,
which comprises two members,
wherein one surface of the first member is processed such that a multitude of tooth-projections projects from said surface,
wherein a second member is mechanically connected to the tips of said projections,
and wherein said second member consists of material which substantially changes its dimensions when being subjected to external influences and therefore changes the distances between adjacent tips of said projections.

3. Actuator according to claim 2,
wherein said first member consists of metal.

4. Actuator according to claim 2,
wherein said second member consists of piezo-active material which is equipped with electrodes for application of voltage between the electrodes.

5. Actuator according to claim 2,
wherein said second member consists of electrically conducting material,
wherein said second member is caused to change its temperature by electrical current applied to it,
and whereby the changes in dimensions caused by the changes in temperature bend the actuator.

6. Actuator according to claim 1,
which comprises three members,
wherein the middle member consists of substantially strong and flexible material,
wherein two adjacent surfaces of said middle member are processed such that a multitude of tooth-shped projections projects from said surfaces,
wherein a second member is mechanically connected to the tips of said projections at one of said surfaces of said middle member,
wherein a third member is mechanically connected to the tips of said projections at the other one of said surfaces of said middle member,
and wherein said second and third members consist of material which substantially changes its dimensions when being subjected to external influences and therefore changes the distances between adjacent tips of said projections connected to said second and third members.

7. Actuator according to claim 6,
wherein said middle member consists of metal.

8. Actuator according to claim 6,
wherein said second and third members consist of piezo-active material which is equipped with electrodes.

9. Actuator according to claim 6,
wherein said second member is mechanically disconnected from said tips of said projections adjacent to its surface,
and wherein said third member is equipped with a multitude of electrodes which allow a structured movement of said tips of said projections relative to said second member,
whereby by appropriate steering of said structured movement an overall movement of said second member in relation to the other members is achieved.

10. Actuator according to claim 9, wherein the lengths of said projections at one surface of said middle member are substantially different from the lengths of said projections, at the other surface of said middle member.

11. Actuator according to claim 9,
comprising a multitude of actuators according to claim 9, which are centrally aligned along a central shaft, and a housing,
wherein said second members are mechanically connected to said shaft and said middle and third members are disconnected from the shaft but connected to a surrounding housing, such that by appriopriate excitation of said electrodes a turning movement of the shaft in relation to the housing is achieved.

12. Actuator according to claim 1,
comprising a multitude of sub-segments, which are pre-bent and arranged in a chain such that a small bending of said sub-segments results in a substantially larger overall displacement of the ends of said chain in relation to each other.

13. Actuator according to claim 6,
comprising a multitude of sub-segments, which are pre-bent and arranged in a chain such that a small bending of said sub-segments results in a substantially larger overall displacement of the ends of said chain in relation to each other.

14. Actuator according to claim 12,
consisting of a double row of said sub-segments, wherein the sub-segments of one row are interconnected at their ends with the sub-segments of the other row.

15. Actuator according to claim 12,
wherein said sub-segments are arranged in the shape of a star.

16. Actuator comprising a multitude of actuators according to claim 1 which are embedded into a sheet of substantially flexible material.

17. Actuator comprising a multitude of actuators according to claim 6 which are embedded into a sheet of substantially flexible material.
